(19) United States
(12) Patent Application Publication
(10) Pub. No.: US 2015/0371823 A1
(43) Pub. Date: Dec. 24, 2015

(54) PLASMA APPARATUS AND SUBSTRATE PROCESSING APPARATUS

(71) Applicant: Wintel Co., Ltd., Gyeonggi-do (KR)

(72) Inventors: Sung-Hwan Eom, Gyeonggi-do (KR); Kee-Su Lee, Gyeonggi-do (KR)

(21) Appl. No.: 14/747,657

(22) Filed: Jun. 23, 2015

Related U.S. Application Data
(63) Continuation of application No. PCT/KR2013/011372, filed on Dec. 10, 2013.

(30) Foreign Application Priority Data
Dec. 28, 2012 (KR) 10-2012-0156371

(51) Int. Cl. H01J 37/32; C23C 16/505

(52) U.S. Cl. CPC H01J 37/321; C23C 16/505; H01J 37/3211

(57) ABSTRACT

A plasma generating apparatus includes peripheral dielectric tubes arranged at regular intervals around a circumference having a constant radius from the center of top surface of a chamber, peripheral antennas disposed to cover the peripheral dielectric tubes, upper magnets vertically spaced apart from the peripheral dielectric tubes to be disposed on the same first plane, and lower magnets each being disposed on the same second plane between the upper magnets and the peripheral dielectric tubes. A central axis of the upper magnets and a central axis of the lower magnets match each other, and plasma is generated inside the peripheral dielectric tubes.

### CROSS-REFERENCE TO RELATED APPLICATIONS

This application is a continuation of and claims priority to PCT/KR2013/011372 filed on Dec. 10, 2013, which claims priority to Korea Patent Application No. 10-2012-0156371 filed on Dec. 28, 2012, the entireties of which are both incorporated by reference herein.

### BACKGROUND

1. Technical Field

The present disclosure generally relates to plasma generating apparatuses and, more particularly, to an inductively coupled plasma generating apparatus using a plurality of antennas.

2. Description of the Related Art

Helicon plasma may generate high-density plasma. However, it is difficult for the helicon plasma to provide process uniformity and process stability.

### SUMMARY

Embodiments of the present disclosure provide a plasma generating apparatus that generates uniform helicon plasma or uniform inductively coupled plasma.

A plasma generating apparatus according to an embodiment of the present disclosure includes: peripheral dielectric tubes arranged at regular intervals around a circumference having a constant radius from the center of top surface of a chamber; peripheral antennas disposed to cover the peripheral dielectric tubes; upper magnets vertically spaced apart from the peripheral dielectric tubes to be disposed on the same first plane; and lower magnets each being disposed on the same second plane between the upper magnets and the peripheral dielectric tubes. A central axis of the upper magnet and a central axis of the lower magnet may match each other, and plasma may be generated inside the peripheral dielectric tubes.

In an example embodiment, the upper magnets may be toroidal permanent magnets, and a magnetization direction of the upper magnets may be a toroidal central axis direction.

In an example embodiments, the lower magnets may be toroidal permanent magnets, a magnetization direction of the lower magnets may be a toroidal central axis direction, the magnetization direction of the upper magnet may be identical to that of the lower magnet, and an external diameter of each of the upper magnets may be equal to or greater than that of each of the lower magnets.

In an example embodiment, the plasma generating apparatus may further include a first RF power supply configured to supply power to the peripheral antennas; and a power distribution unit configured to distribute the power to the peripheral antennas.

In an example embodiment, the power distribution unit may include a coaxial-cable type input branch to receive power from the first RF power supply; a three-way branch connected to the input branch, the three-way branch splitting into three sections; coaxial-cable type T branches connected to the three-way branch to split into two sections; and ground lines connecting an outer cover of the T branches to the peripheral antennas. An internal conductor of the T branches may be connected to one end of each of the peripheral antennas, and the outer cover of the T branches may be connected to the other end of each of the peripheral antennas.

In an example embodiment, the plasma generating apparatus may further include a central dielectric tube disposed in the center of the top surface of the chamber; and a central antenna disposed around the central dielectric tube.

In an example embodiment, a direction of a magnetic field inside the peripheral dielectric tubes and a direction of a magnetic field inside the central dielectric tube may be opposite to each other.

In an example embodiment, the chamber may include a lower chamber of a metal material; an upper chamber of a nonmetal material continuously connected to the lower chamber; and a top plate of a metal material to cover a top surface of the upper chamber. The chamber further may further include a side coil to cover a side surface of the upper chamber. The side coil may generate inductively coupled plasma inside the chamber.

### BRIEF DESCRIPTION OF THE DRAWINGS

The present disclosure will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present disclosure.

FIG. 1 is a top plan view illustrating antenna arrangement of a conventional helicon plasma generating apparatus.

FIG. 2 is a cross-sectional view taken along the line I-I′ in FIG. 1 and shows a computer simulation result indicating a magnetic field profile.

FIG. 3 is a cross-sectional view taken along the line II-II′ in FIG. 1 and shows a computer simulation result indicating a magnetic field profile.

FIG. 4 is a perspective view of a plasma generating apparatus according to an embodiment of the present disclosure.

FIG. 5 is a perspective view of an upper magnet and a lower magnet in FIG. 4.

FIG. 6 is a top plan view illustrating arrangement relationship of dielectric tubes in FIG. 5.

FIG. 7 is a conceptual cross-sectional view of the plasma generating apparatus in FIG. 4.

FIG. 8 is a circuit diagram of the plasma generating apparatus in FIG. 4.

FIG. 9 illustrates dielectric tubes in FIG. 4.

FIG. 10A is a perspective view of a power distribution unit in FIG. 1.

FIG. 10B is a cross-sectional view taken along the line III-III′ in FIG. 10A.

FIG. 10C is a cross-sectional view taken along the line IV-IV′ in FIG. 10A.

FIG. 10D is a cross-sectional view taken along the line V-V′ in FIG. 10A.

FIG. 11A is a cross-sectional view taken along the line VI-VI′ in FIG. 6 and describes a magnetic field.

FIG. 11B is a cross-sectional view taken along the line VII-VII′ in FIG. 6 and describes a magnetic field.

FIG. 12 a cross-sectional view of a plasma generating apparatus according to another embodiment of the present disclosure.

FIG. 13A illustrates a thickness distribution of a silicon oxide layer deposited using a plasma generating apparatus having the structure in FIG. 1.

FIG. 13B illustrates a thickness distribution of a silicon oxide layer deposited using a plasma generating apparatus having the structure in FIG. 5.

### DETAILED DESCRIPTION

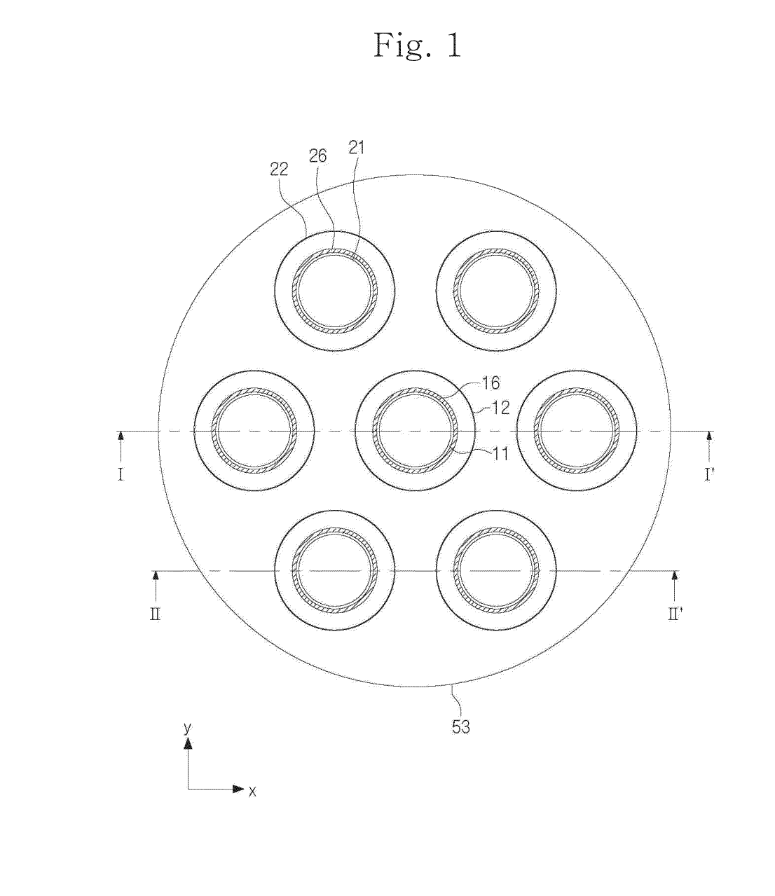

FIG. 1 is a top plan view illustrating antenna arrangement of a conventional helicon plasma generating apparatus.

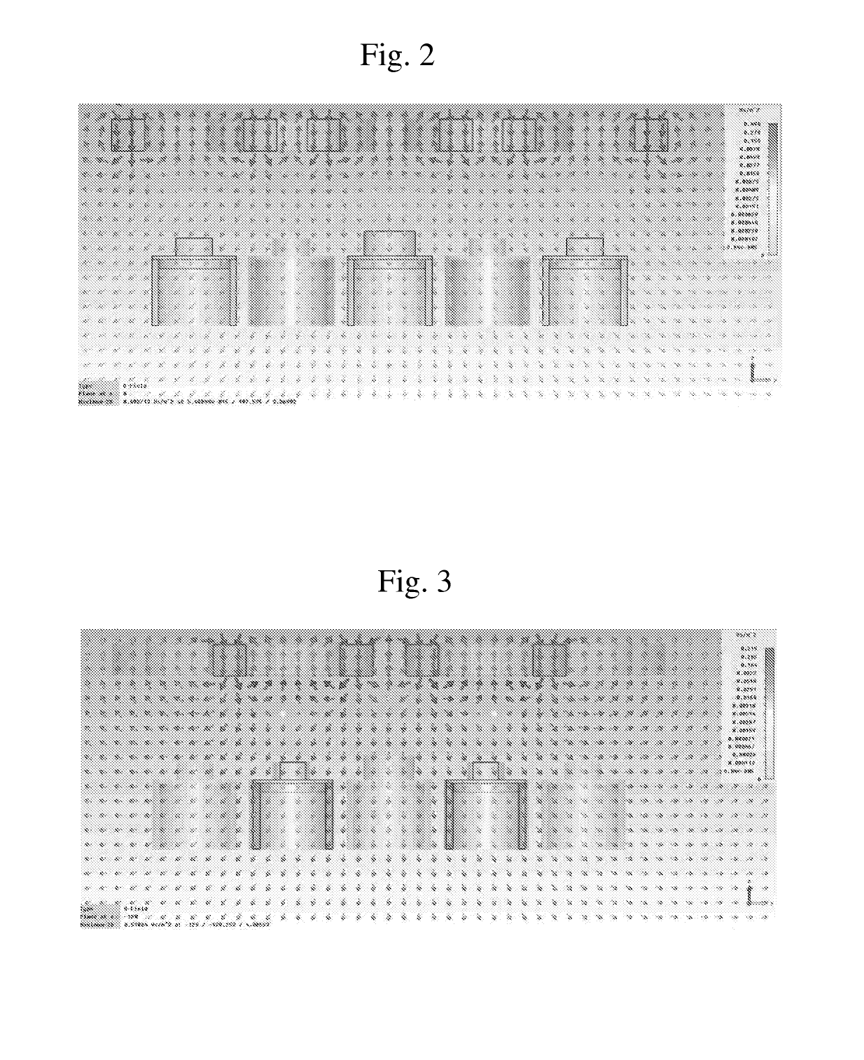

FIG. 2 is a cross-sectional view taken along the line I-I′ in FIG. 1 and shows a computer simulation result indicating a magnetic field profile.

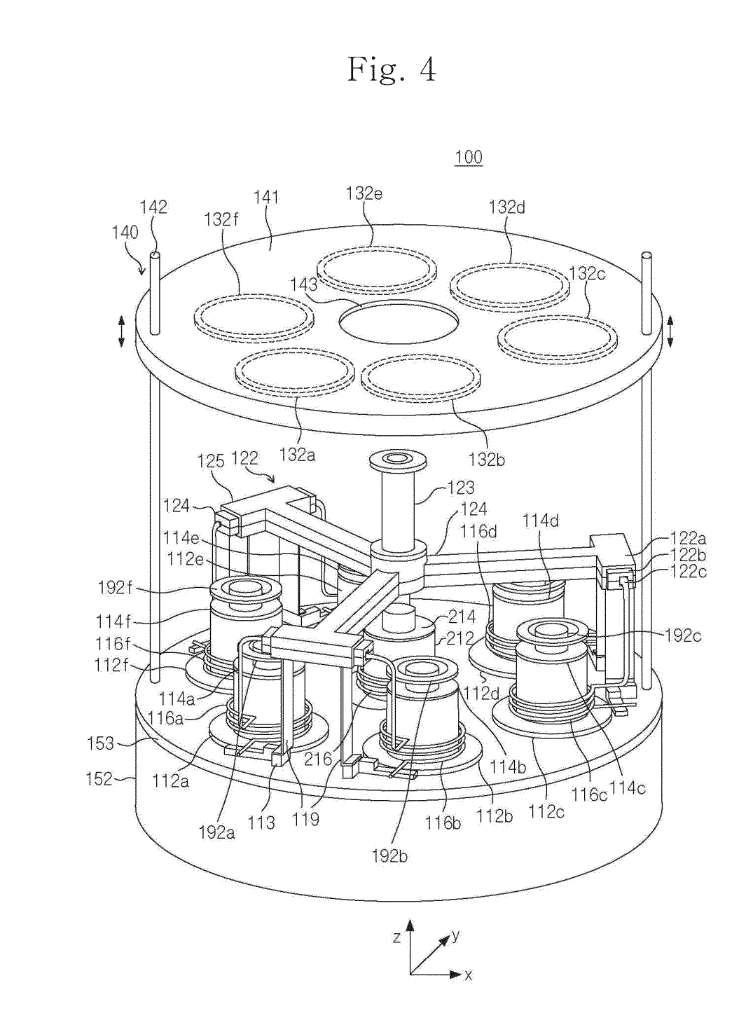

FIG. 3 is a cross-sectional view taken along the line II-II′ in FIG. 1 and shows a computer simulation result indicating a magnetic field profile.

Referring to FIGS. 1 to 3, seven dielectric tubes are disposed on a top plate 53 of a cylindrical chamber. A central dielectric tube 11 is disposed in the center of the top plate 53, and six peripheral dielectric tubes 11 are symmetrically disposed at regular intervals on a circumference having a constant radius around the center of the top plate 53. In addition, a central antenna 16 covers the central dielectric tube 11. A peripheral antenna 26 covers the peripheral dielectric tube 21. In order to generate helicon plasma, permanent magnets 12 and 22 are disposed to be vertically spaced apart from the central antenna 16 and the peripheral antenna 26.

According to a computer simulation, when a single permanent magnet is used for each of a conventional dielectric tube, a magnetic field obliquely impinges on a side surface of the dielectric tube. Thus, plasma generated by an antenna covering the dielectric tube impacts on an inner wall of the dielectric tube. That is, electrons move along a magnetic field and impact on the inner wall of the dielectric tube to generate heat. Accordingly, loss of the electrons increases to decrease plasma density and stability of an apparatus is reduced by the heat. In particular, an antenna covering a central dielectric tube increases plasma density on a substrate in the center of a chamber. Accordingly, it is difficult to uniformly perform a process.

According to a test result and a computer simulation result, when only one permanent magnet is disposed at each dielectric tube, the peripheral antennas 116a to 116f connected in parallel cannot generate uniform plasma on a substrate inside a chamber. This is because a direction of a magnetic field deviates from a z-side direction within a dielectric tube below permanent magnets. Accordingly, a novel magnet structure for generating uniform plasma is required.

Preferred embodiments of the present disclosure will be described below in more detail with reference to the accompanying drawings. The present disclosure may, however, be embodied in different forms and should not be constructed as limited to the embodiments set forth herein. Rather, these embodiments are provided so that this disclosure will be thorough and complete, and will fully convey the scope of the present disclosure to those skilled in the art. Like numbers refer to like elements throughout.

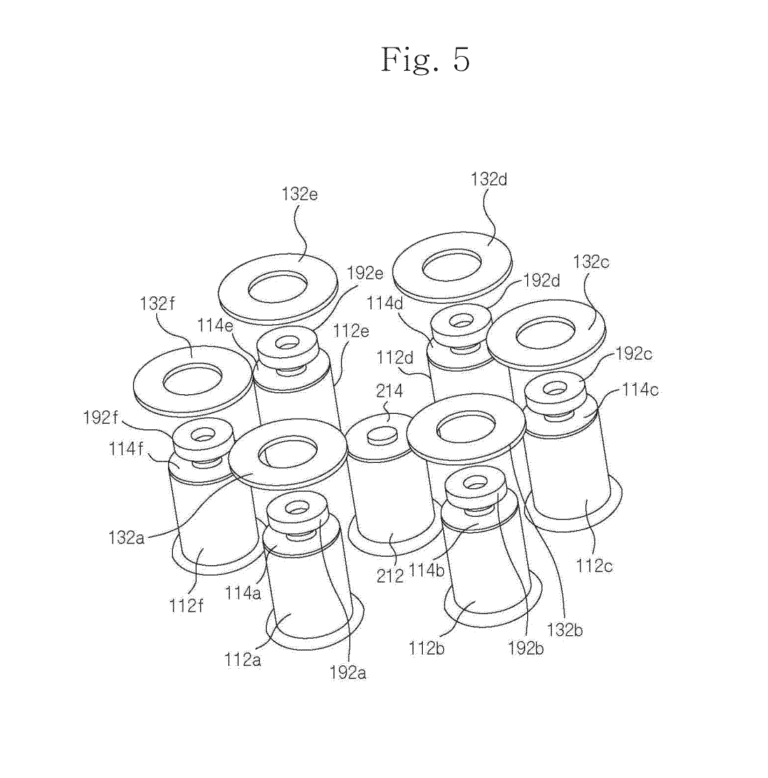

FIG. 4 is a perspective view of a plasma generating apparatus according to an embodiment of the present disclosure.

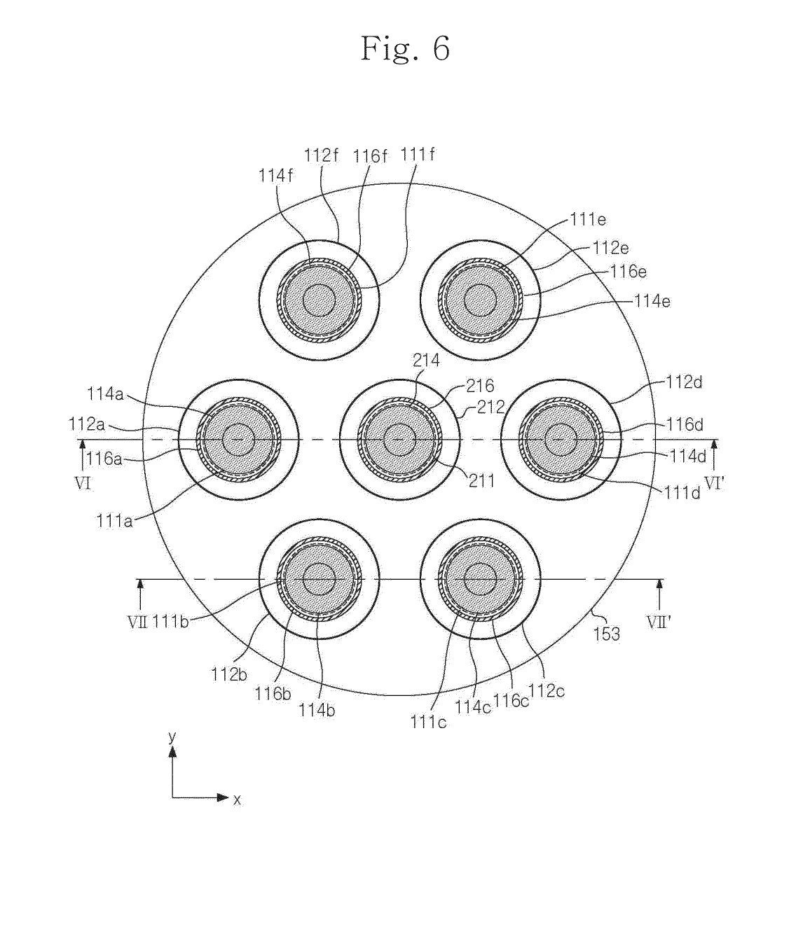

FIG. 5 is a perspective view of an upper magnet and a lower magnet in FIG. 4.

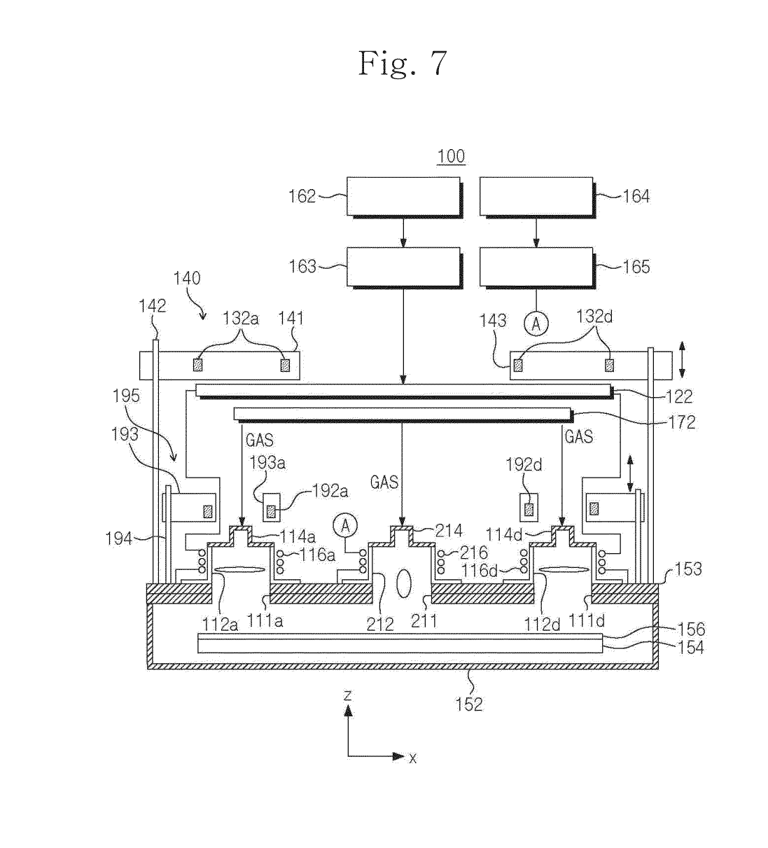

FIG. 6 is a top plan view illustrating arrangement relationship of dielectric tubes in FIG. 5.

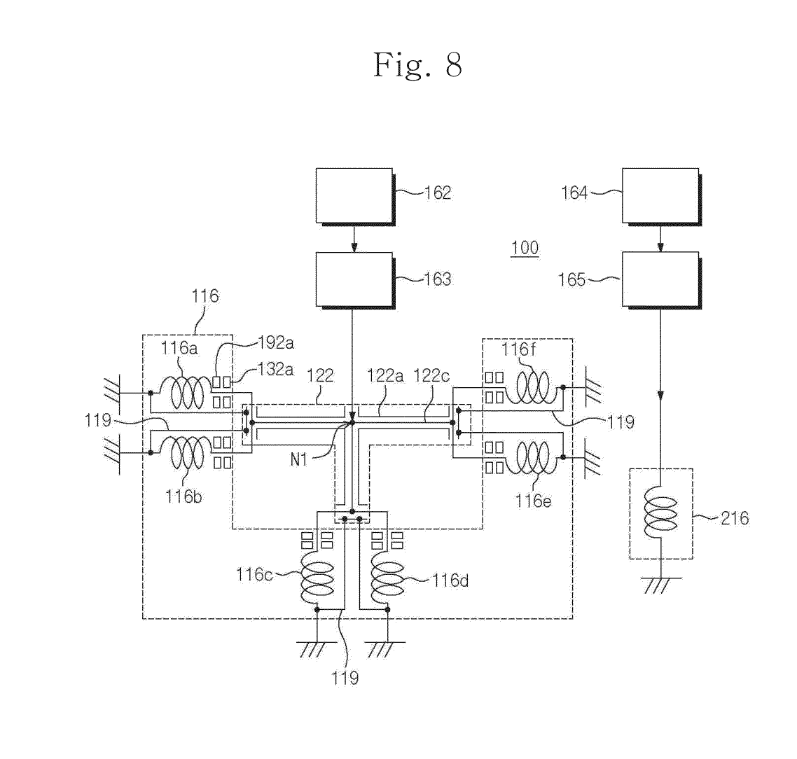

FIG. 7 is a conceptual cross-sectional view of the plasma generating apparatus in FIG. 4.

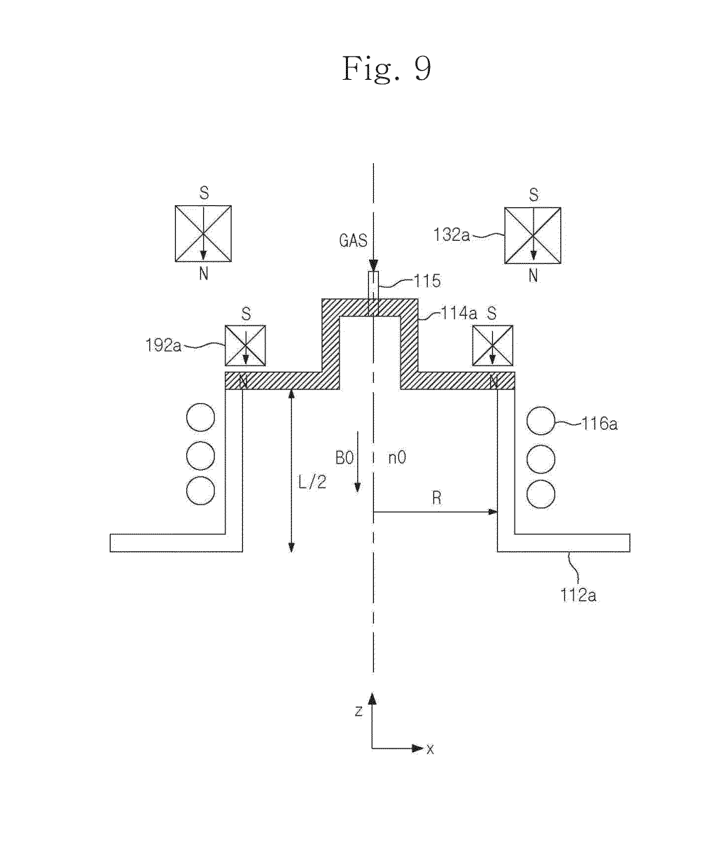

FIG. 8 is a circuit diagram of the plasma generating apparatus in FIG. 4.

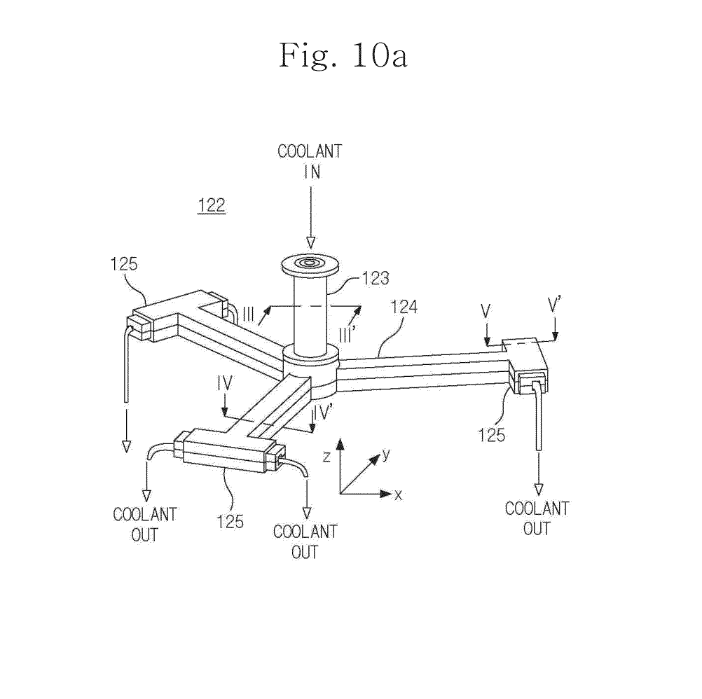

FIG. 9 illustrates dielectric tubes in FIG. 4.

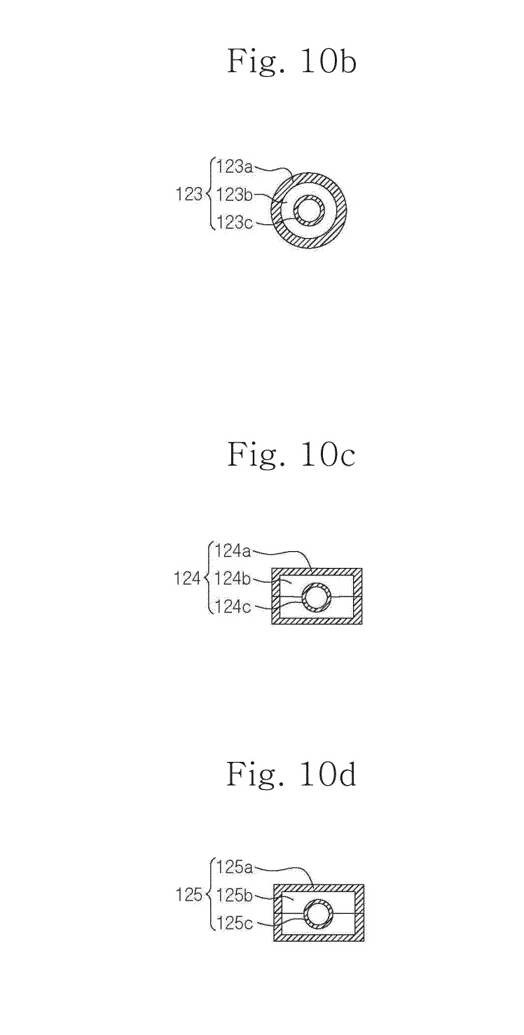

FIG. 10A is a perspective view of a power distribution unit in FIG. 1.

FIG. 10B is a cross-sectional view taken along the line III-III′ in FIG. 10A.

FIG. 10C is a cross-sectional view taken along the line IV-IV′ in FIG. 10A.

FIG. 10D is a cross-sectional view taken along the line V-V′ in FIG. 10A.

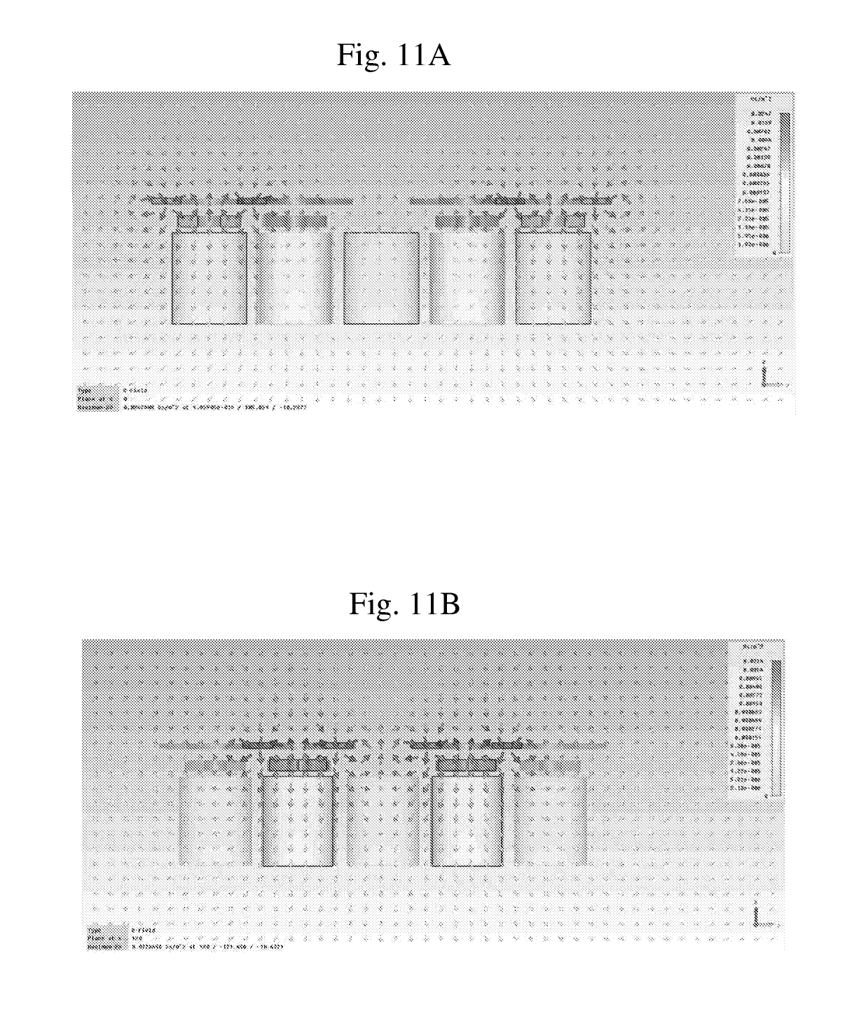

FIG. 11A is a cross-sectional view taken along the line VI-VI′ in FIG. 6 and describes a magnetic field.

FIG. 11B is a cross-sectional view taken along the line VII-VII′ in FIG. 6 and describes a magnetic field.

Referring to FIGS. 4 to 9 and FIGS. 10A to 10D, a plasma generating apparatus 100 includes peripheral dielectric tubes 112a to 112f arranged at regular intervals around a circumference having a constant radius from the center of top surface 153 of a chamber 152, peripheral antennas 116a to 116f disposed to cover the peripheral dielectric tubes 112a to 112f, upper magnets 132a to 132f vertically spaced apart from the peripheral dielectric tubes 112a to 112f to be disposed on the same first plane, and lower magnets 192a to each being disposed on the same second plane between the upper magnets 132a to 132f and the peripheral dielectric tubes 112a to 112f. A central axis of the upper magnet 132a and a central axis of the lower magnet 192a match each other.

The chamber 152 may be in the form of a cylinder or a square tube. The chamber 152 may include a gas supply part to supply a gas and an exhaust part to exhaust the gas. The chamber 152 may include a substrate holder 154 and a substrate 156 mounted on the substrate holder 154. The chamber 152 may have a top surface 153. The top surface 153 may be a cover of the chamber 152. The top surface 153 may be formed of a metal or a metal-alloy. The top surface 153 may be disposed on an x-y plane.

Peripheral through-holes 111a to 111f may be formed on the top surface 153. The top surface 153 may be in the form of a square plate or a disc. The peripheral through-holes 111a to 111f may be arranged at regular intervals on the circumference having a constant radius in the center of the top surface 153. An internal diameter of the peripheral through-hole 111a may be substantially equal to that of the peripheral dielectric tube 112a. A central through-hole 211 may be formed in the center of the top surface 153.

The peripheral dielectric tubes 112a to 112f may be disposed on the peripheral through-holes 111a to 111f, respectively. A central dielectric tube 212 may be disposed on the central through-hole 211. The top surface 153 may be formed by connecting two plates to each other. Thus, a flow path through which a coolant may flow may be formed in the top surface 153.

The peripheral dielectric tubes 112 to 112f and the central dielectric tube 212 may each be in the form of a bell-jar having no cover. The peripheral dielectric tubes 112 to 112f and the central dielectric tube 212 may each include a washer-shaped support part and a cylindrical part. The insides of the peripheral dielectric tubes 112a to 112f and the inside of the central dielectric tube 212 may be maintained at a vacuum state.

The peripheral dielectric tubes 112a to 112f and the central dielectric tube 212 may be formed of glass, quartz, alumina, sapphire or ceramic. One end of the central dielectric tube 212 may be connected to the central through-hole 211 of the chamber 152, and the other end thereof may be connected to a metal cover 214.

One end of each of the peripheral dielectric tubes 112a to 112f may be connected to each of the peripheral through-holes 111a to 11f of the chamber 1520, and the other end of each of the peripheral dielectric tubes 112a to 112f may be connected to each of metal covers 114a to 114 f. The metal covers 114a to 114f may include a gas inlet 115. The metal covers 114a to 114f may reflect a helicon wave to cause constructive interference. Length of each of the peripheral dielectric tubes 112a to 112f may be between several centimeters and tens of centimeters. The length of each of the peripheral dielectric tubes 112a to 112f may be decided by a radius R of a dielectric tube, magnetic flux intensity B₀ in a peripheral dielectric tube, plasma density n₀, and a frequency f of power.

When a radius is R and assuming that plasma inside the peripheral dielectric tube is uniform, radial current density at walls of the peripheral dielectric tubes 112a to 112f is zero with respect to a helicon mode in which m=0. The length (L/2=π/kz) of each of the peripheral dielectric tubes 112a to 112f corresponds to half wavelength of a helicon wave and is given by the Equation (1) wherein kz represents the wave number of the helicon wave.

$${k}_{z}^{4} + {( \frac{3.83}{R} )}^{2} {k}_{z}^{2} - {( \frac{e {μ}_{0} {n}_{0} ω}{{B}_{0}} )}^{2} = 0 \qquad Equation ( 1 )$$

In the Equation (1), e represents charge on electrons, B₀ represents magnetic flux intensity, μ₀ represents magnetic permeability, ω represents an angular frequency, and n₀ represents plasma density. When the frequency f is 13.56 MHz, B₀ is 90 Gauss, and n₀ is 4×10¹² cm⁻³, the length L/2 of the peripheral dielectric tube may be 5.65 cm.

The peripheral antennas 116a to 116f may have geometrical symmetrical symmetry. The peripheral antennas 116a to 116f may have the same structure and may be electrically connected in parallel. Each of the peripheral antennas 116a to 116f may be a conductive pipe that is in the form of a cylinder or a square tube. A coolant may flow into the peripheral antennas 116a to 116f.

The peripheral antennas 116a to 116f may be symmetrically disposed around the circumference having a constant radius on the basis of the center of the top surface 153. The central antenna 216 may be disposed in the center of the top surface 153. The number of the peripheral antennas 116a to 116f may be six. The peripheral antennas 116a to 116f may be disposed to cover the peripheral dielectric tube. Each of the peripheral antennas 116a to 116f may be a three-turn antenna. The peripheral antenna 216 may be provided in singularity. The central antenna 216 may be disposed to cover the central dielectric tube. The central antenna 216 may have the same structure as the peripheral antenna or have a different structure than the peripheral antenna.

The peripheral antennas 116a to 116f may generate helicon plasma at a low pressure of several milliTorr by using a magnetic field established by the upper magnets 132a to 132f and the lower magnets 192a to 192f. The peripheral antenna may increase plasma density inside the peripheral dielectric tube. In addition, the central antenna may generate not helicon plasma but inductively coupled plasma. Thus, the peripheral dielectric tube may maintain high plasma density by the helicon plasma and the central dielectric tube may maintain relatively low plasma density by the inductively coupled plasma. The helicon plasma and the inductively coupled plasma may be diffused onto the substrate to form a generally uniform plasma density distribution.

A direction of the magnetic field established by the upper magnets 132a to 132f and the lower magnets 192a to 192f may be a negative z-axis direction inside the peripheral dielectric tube. In addition, since magnets are not disposed on the central dielectric tube, a direction of a magnetic may be a positive z-axis direction inside the central dielectric tube. The density of the helicon plasma inside the peripheral dielectric tube may be higher than that of the inductively coupled plasma inside the central dielectric tube. Thus, the general plasma density distribution on the substrate may be improved. Moreover, sputtering damage and thermal damage to the helicon plasma may be suppressed inside the peripheral dielectric tube.

A first RF power supply 162 may output a sine wave of a first frequency. The power of the first RF power supply 162 may be supplied to a first power distribution unit 122 through a first impedance matching network 163. A frequency of the first RF power supply 162 may be between hundreds of kHz and hundreds of MHz.

The first power distribution unit 122 may distribute the power received through the first impedance matching network 163 to the peripheral antennas 116a to 116f connected in parallel. The first power distribution unit 122 may include a first power distribution line 122c and a first conductive outer cover 122a that covers the first distribution line 122c and is grounded. Distances between an input terminal N1 of the first power distribution unit 122 and the peripheral antennas 116a to 116f may be equal to each other. A first insulating part may be disposed between the first power distribution line 122c and the first conductive outer cover 122a.

The first power distribution unit 122 may include a coaxial-cable type input branch 123 to receive power from the first RF power supply 162, a coaxial-cable type three-way branch 124 that is connected to the input branch 123 and splits into three branches, and a coaxial-cable type T branches 125 that are connected to the three-way branch 124 to split into two branches.

The input branch 123 may be in the form of a cylinder. The input branch 123 has a coaxial cable structure. The input branch 123 may include a cylindrical inner conductor 123c, a cylindrical insulator 123b to cover the inner conductor 123c, and a cylindrical outer conductor 123a to cover the insulator 123b. A coolant may flow to the inner conductor 123c.

One end of the input branch 123 may be connected to the first impedance matching network 163, and the other end thereof may be connected to the three-way branch 124 that splits at regular intervals of 120 degrees.

The three-way branch 124 may be in the form of a square tube cut along an axis. The three-way branch 124 may be disposed on an x-y plane spaced apart from a top plate in the z-axis direction. The three-way branch 124 may have a coaxial cable structure. The three-way branch 124 may include a cylindrical inner conductor 124, an insulator 124b in the form of a cut square tube to cover the inner conductor 124c, and an outer conductor 124a in the form of a cut square tube to cover the insulator 124b. The coolant provided through the inner conductor 123c of the input branch 123 may flow into the inner conductor 124c of the three-way branch 124. Length of an arm of the three-way branch 124 may be greater than a distance from the center of the top surface to a disposition position of the peripheral dielectric tube. Thus, electrical connection between the T branches 125 and the peripheral antennas may be easily established.

The T branches 125 may be connected to the three-way branch 124 to split into two branches. Each of the T branches 125 may be in the form of a cut square tube. Each of the T branches 125 may have a coaxial cable structure. Each of the T branches 125 may include a cylindrical inner conductor 125c, an insulator 125b to cover the inner conductor 125c, and an outer conductor 125a to cover the insulator 125b. The coolant may flow into the inner conductor 125c. The branches 125 may have an arm of the same length.

Each of the T branches 125 may supply power to a pair of peripheral antennas 116a and 116b. The T branches 125 may have the same shape. The inner conductor 125c may be successively connected to the peripheral antennas 116a and 116b to supply power and the coolant at the same time. The coolant provided through the inner conductor 124c of the three-way branch 124 may flow into the inner conductor 125c of the T branch 125.

Fixing plates 113 may fix the peripheral antennas 116a to 116f and may be fixed to the top surface 153. The fixing plates 113 may be in the form of a strip line. One end of each of the fixing plates 113 may be connected to one end of each of the peripheral antennas 116a to 116f to be grounded. The other end of each of the fixing plates 113 may be connected to one end of a ground line 119 to be grounded.

The ground line 119 may connect the fixing plate 113 and the outer conductor 125a of the T branch 125 to each other. One end of the ground line 119 may be connected to the other end of the fixing plate 113, and the other end of the ground line 119 may be connected to the outer conductor 125a of the T branch 125. Lengths between the ground line 119 and the peripheral antennas 116a to 116f may be equal to each other. Thus, all the peripheral antennas 116a to 116f may have the same impedance.

The gas distribution part 172 may supply a gas to the peripheral dielectric tubes and/or the central dielectric tube. The gas distribution unit 172 may have a similar structure to a single first power distribution unit 122 and may uniformly distribute a gas to dielectric tubes. The gas distribution part 172 may be connected to the metal covers 114a to 114f. The gas distribution part 172 may be formed to have the same length with respect to the metal covers 114a to 114f. More specifically, the gas distribution part 172 may branch into three sections at a central metal cover 214 and may branch again into a T shape to be connected to the metal covers 114a to 114f.

A second RF power supply 164 may supply power to the central antenna 216. A first frequency of the first RF power supply 162 and a second frequency of the second RF power supply 164 may be different from each other to minimize interference of the first RF power supply 162 and the second RF power supply 164. For example, the first frequency may be 13.56 MHz and the second frequency may be 12 MHz.

The second RF power supply 164 may be directly connected to the central antenna 216 through a second impedance matching network 165.

Each of the upper magnets 132a to 132f may be in the form of a donut or a toroid. A section of each of the upper magnets 132a to 132f may be quadrangular or circular. A magnetization direction of the upper magnets may be perpendicular to a plane on which the upper magnetic is disposed. Each of the upper magnets 132a to 132f may be a toroidal permanent magnet. A magnetization direction of the upper magnets 132a to 132f may be a central axis direction of the toroidal shape.

The upper magnets 132a to 132f may be inserted into an upper magnet fixing plate 141. The upper magnet may be disposed to be spaced from the center of the peripheral antenna in a z-axis direction. The upper magnet fixing plate 141 may be disc-shaped or quadrangular and may be a nonmagnetic material.

An upper magnet moving part 140 may be fixedly connected to the top plate 153. The upper magnet moving part 140 may at least one upper magnetic support pillar 142 extending perpendicularly to a plane (x-y plane) on which the peripheral dielectric tubes are disposed. The upper magnet fixing plate 141 may be inserted into the upper magnet support pillar 142 to move along the upper magnet support pillar 142. A through-hole 143 may be formed in the center of the upper magnet fixing plate 141. The input branch 123 may be connected to the first impedance matching network 163 via the through-hole 143.

The upper magnetic fixing plate 141 may be structure or means for fixing the upper magnets 132a to 132f. The upper magnets 132a to 132f may be spaced apart from the center of the peripheral antennas 116a to 116f in the z-axis direction. The center of the upper magnet may be disposed to be aligned with the center of the peripheral dielectric tube. The upper magnets 132a to 132f may be inserted into the upper magnet fixing plate 141 to be fixed thereto.

The lower magnets 192a to 192f may be disposed on the same second plane between the upper magnets 132a to 132f and the peripheral dielectric tubes 112 a to 112f, respectively. Central axes of the upper magnet and the lower magnet may match each other. Each of the lower magnets 192a to 192f may be a toroidal permanent magnet. A magnetization direction of the lower magnets 192a to 192f may be a central axis direction of the toroidal shape. The magnetization of the upper magnet may be identical to that of the lower magnet. An external diameter of each of the upper magnets 132a to 132f may be equal to or greater than that of each of the lower magnets 192a to 192f. The lower magnet may be disposed between the upper magnet and the metal cover of the peripheral dielectric tube. In this case, a magnetic field established by the upper magnet and the lower magnet may be prevented from obliquely impinging on a side surface of the peripheral dielectric tube. As a result, a plasma density distribution on a substrate may be uniform. In addition, helicon plasma inside the peripheral dielectric tube may be prevented from heating the peripheral dielectric tube.

Referring to FIGS. 11A and 11 B, a direction of a magnetic field inside the peripheral dielectric tube established by the lower magnets 192a to 192f and the upper magnets 132a to 132f may be a negative z-axis direction and a direction of a magnetic field inside the central dielectric tube established by the lower magnets 192a to 192f and the upper magnets 132a to 132f may be a positive z-axis direction.

A lower magnet moving part 195 may be fixedly connected to the top surface 153. The lower magnet moving part 195 may include at least one lower magnet support pillar 194 extending perpendicularly to a plane (x-y plane) on which the peripheral dielectric tubes are disposed. The low magnet fixing plate 193 may be inserted into the lower magnet support pillar 194 to move along the lower magnet support pillar 194. A through-hole may be formed in the center of the lower magnet fixing plate 193. The input branch 123 may be connected to the first impedance matching network 163 via the through-hole.

The lower magnet fixing plate 193 may be structure or means for fixing the lower magnet 192a to 192f. The lower magnets 192a to 192f may be spaced apart from the center of the peripheral antennas in the z-axis direction. The center of the lower magnet may be disposed to be aligned with that of the peripheral dielectric tube. The lower magnets 192a to 192f may be inserted into the low magnet fixing plate 193 to be fixed thereto. The lower magnet fixing plate 193 may have a through-hole 193a formed at a position where the lower magnet is disposed. A gas line may be adapted to provide a gas to the peripheral dielectric tube.

The upper magnet moving part 140 and the lower magnet moving part 195 may adjust the intensity and distribution of flux density B₀ inside a peripheral dielectric tube to generate a planar helicon mode. For example, the upper magnetic fixing plate 141 and the lower magnet fixing plate 193 may move such that a ratio of plasma density n₀ to the flux density B₀ (B₀ /n₀ ) is constant with respect to the given conditions L, ω, and R. Thus, uniform plasma may be generated.

According to an example embodiment of the present disclosure, an upper magnet and a lower magnet may be used to prevent a magnetic field from obliquely impinging on a peripheral dielectric tube. A direction of the magnetic field inside the peripheral dielectric tube may be a negative z-axis direction, and a direction of the magnetic field inside a central dielectric tube may be a positive z-axis direction. The intensity of the magnetic field inside the peripheral dielectric tube may be much smaller than that of the magnetic field inside the central dielectric tube.

In addition, the upper magnet and the lower magnet may be used to adjust a region and a position where plasma is generated. More specifically, a position where the helicon plasma is generated may be disposed inside or on a bottom surface of the peripheral dielectric tube.

Moreover, when a central antenna generates plasma, plasma density increases in a central region inside a chamber to make it difficult to generate uniform plasma. Thus, uniformity of a plasma density distribution is reduced. Preferably, the central antenna does not generate helicon plasma to increase the uniformity of the plasma density distribution. As a result, a magnet is removed on the central antenna. Accordingly, a central antenna covering the central dielectric tube may generate not helicon plasma but conventional inductively coupled plasma. Thus, plasma density in the center of a chamber may be reduced to make a uniform process possible. According to an example embodiment of the present disclosure, a uniform process may be performed on a substrate within the range of 3 percent.

In order to generate large-area plasma, a single power supply may supply power to peripheral antennas connected in parallel. A power distribution unit may be disposed between the peripheral antennas and the power to equivalently supply the power to the respective peripheral antennas.

For example, one central antenna and six peripheral antennas arranged at regular intervals around a central antenna may be disposed on a top plate of a chamber. The central antenna may be disposed in the center of the top plate, and the six peripheral antennas may be symmetrically disposed on a predetermined circumference on the basis of the central antenna. The six peripheral antennas may be connected to one power via the power distribution unit.

However, when peripheral antennas generate plasma, an impedance of peripheral antennas having symmetry on a circumference and an impedance of a central antenna surrounded by the peripheral antennas are different from each other. Accordingly, power may be concentrated on some antennas to generate non-uniform plasma. Thus, according to an example embodiment of the present disclosure, the peripheral antennas receive power through a first power supply and a first power distribution unit, and the central antenna receives power from a second power supply. As a result, the power supplied to the peripheral antennas and the power supplied to the central antenna may be controlled independently.

In addition, the power distribution unit is in the form of a coaxial cable having the same length from the peripheral antennas. Thus, the peripheral antennas may operate under the same conditions. In order for the power distribution unit to maintain the same impedance, one end of the peripheral antenna must be connected to a power supply line and the other end thereof must be connected to an outer cover constituting the power distribution unit through a ground line having the same length.

As a result, the central antenna generates inductively coupled plasma and the peripheral antennas generate helicon plasma. Thus, uniform and high-density large-area plasma may be generated.

A plasma generating apparatus according to an example embodiment of the present disclosure may perform an oxidation process, a nitridation process or a deposition process.

As the integration density of a semiconductor device increases, there is a need for a plasma generating apparatus having high density at low pressure (several mTorr) capable of adjusting a deposition rate of an oxide layer and depositing a high-purity oxide layer.

Conventionally, an inductively coupled plasma apparatus generate high-density plasma at pressure of tens of mTorr or more. However, it is difficult for the inductively coupled plasma apparatus to generate high-density plasma at low pressure of several mTorr. Accordingly, a low-pressure process and a high-pressure process could not be successively performed inside a single chamber.

A plasma apparatus according to an example embodiment of the present disclosure generates large-area high-density helicon plasma at low pressure of several mTorr. The high-density plasma generated at the low pressure may maximally dissociate an injected gas (e.g., O₂) to form a high-purity oxide layer. In addition, the plasma apparatus may successively generate large-area high-density plasma at high pressure between tens of mTorr and several Torr.

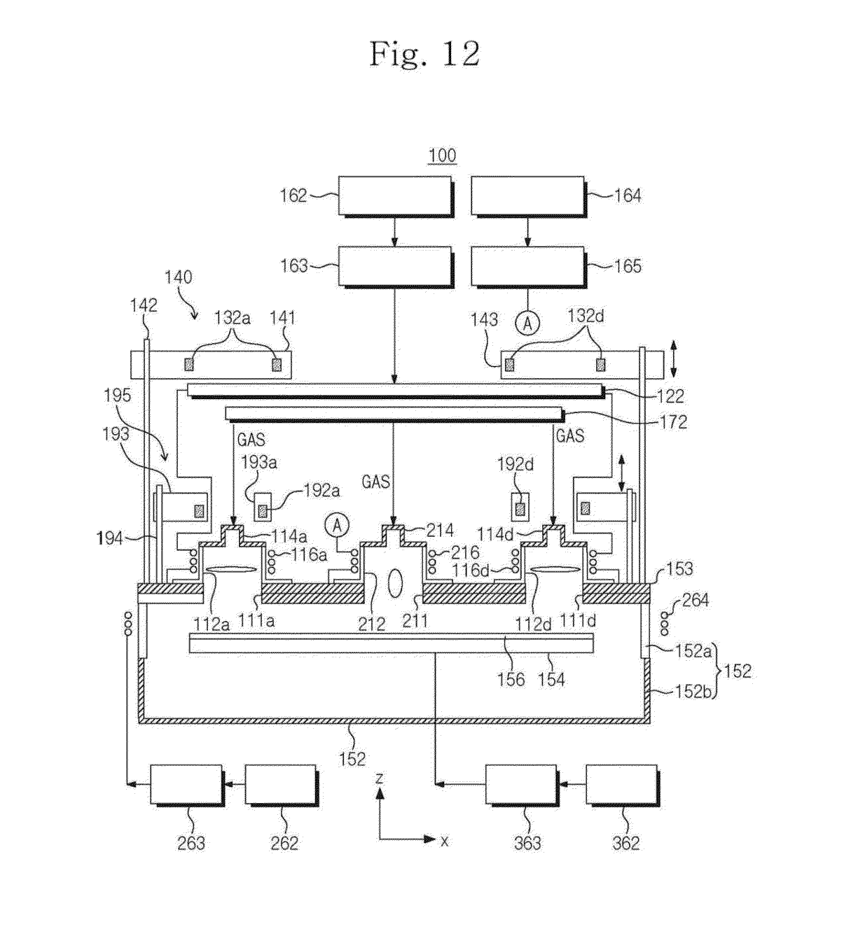

FIG. 12 a cross-sectional view of a plasma generating apparatus according to another embodiment of the present disclosure.

Referring to FIG. 12, a plasma generating apparatus 100 includes peripheral dielectric tubes 112a to 112f arranged at regular intervals on a circumference having a constant radius from the center of a top surface of a chamber 152, peripheral antennas 116a to 116f disposed to cover the peripheral dielectric tubes 112a to 112f, upper magnets vertically spaced apart from the peripheral dielectric tubes 112a to 112f and disposed on the same first plane, and lower magnets 192a to 192f each being disposed on the same second plane between the upper magnets 132a to 132f and the peripheral dielectric tubes 112a to 112f. A central axis of the upper magnet 132a and a central axis of the low magnet 192a match each other.

The chamber 152 includes a lower chamber 152b of a metal material, an upper chamber 152a of a nonmetal material continuously connected to the lower chamber 152, and a top plate 153 of a metal material to cover a top surface of the upper chamber 152a. A side coil 264 may be disposed to wind a side surface of the chamber 152a. The side coil 264 may generate inductively coupled plasma inside the chamber. The side coil 264 may receive power from an RF power supply 262 through an impedance matching network 263. A substrate holder may receive the power from the RF power supply 362 through an impedance matching network 363.

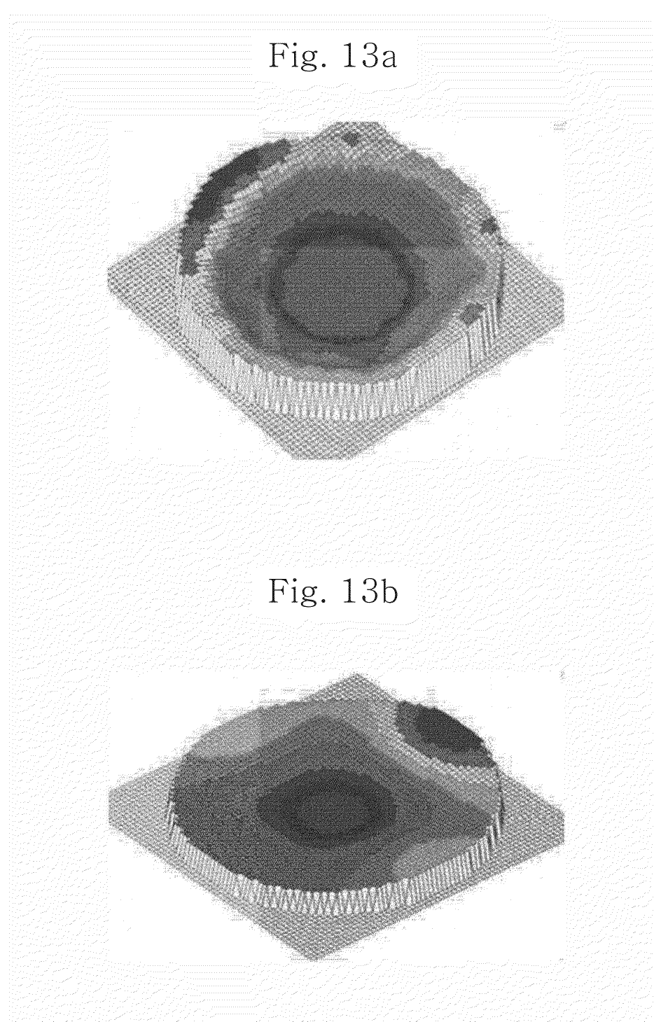

FIG. 13A illustrates a thickness distribution of a silicon oxide layer deposited using a plasma generating apparatus having the structure in FIG. 1.

FIG. 13B illustrates a thickness distribution of a silicon oxide layer deposited using a plasma generating apparatus having the structure in FIG. 5.

Referring to FIGS. 13A and 13B, a sacrificial oxide layer was formed using argon, oxygen, and hydrogen at pressure of 30 mTorr. The uniformity (1-(maximum-minimum)/maximum) of a silicon oxide layer exhibited 82.5 percent with respect to a 300 mm wafer in the plasma generating apparatus having the structure described in FIG. 1 and exhibited 99.15 percent with respect to a 300 mm wafer in the plasma generating apparatus having the structure described in FIG. 3.

As described above, a plasma generating apparatus according to an example embodiment of the present disclosure generates helicon plasma of a two-layered magnet structure around a chamber and does not generate plasma or generates inductively coupled plasma that does not use a magnet in the center of the chamber. Thus, process uniformity and process speed may be significantly improved.

Although the present disclosure has been described in connection with the embodiment of the present disclosure illustrated in the accompanying drawings, it is not limited thereto. It will be apparent to those skilled in the art that various substitutions, modifications and changes may be made without departing from the scope and spirit of the present disclosure.

What is claimed is:

1. A plasma generating apparatus comprising:
peripheral dielectric tubes arranged at regular intervals around a circumference having a constant radius from the center of top surface of a chamber;
peripheral antennas disposed to cover the peripheral dielectric tubes;
upper magnets vertically spaced apart from the peripheral dielectric tubes to be disposed on the same first plane; and
lower magnets each being disposed on the same second plane between the upper magnets and the peripheral dielectric tubes, wherein
a central axis of the upper magnet and a central axis of the lower magnet match each other, and
plasma is generated inside the peripheral dielectric tubes.

2. The plasma generating apparatus of claim 1, wherein
the upper magnets are toroidal permanent magnets, and
a magnetization direction of the upper magnets is a toroidal central axis direction.

3. The plasma generating apparatus of claim 2, wherein
the lower magnets are toroidal permanent magnets,
a magnetization direction of the lower magnets is a toroidal central axis direction,
the magnetization direction of the upper magnet is identical to that of the lower magnet, and
an external diameter of each of the upper magnets is equal to or greater than that of each of the lower magnets.

4. The plasma generating apparatus of claim 1, further comprising:
a first RF power supply configured to supply power to the peripheral antennas; and
a power distribution unit configured to distribute the power to the peripheral antennas.

5. The plasma generating apparatus of claim 4, wherein
the power distribution unit comprises:
a coaxial-cable type input branch to receive power from the first RF power supply;
a three-way branch connected to the input branch, the three-way branch splitting into three sections;
coaxial-cable type T branches connected to the three-way branch to split into two sections; and
ground lines connecting an outer cover of the T branches to the peripheral antennas, wherein
an internal conductor of the T branches is connected to one end of each of the peripheral antennas, and
the outer cover of the T branches is connected to the other end of each of the peripheral antennas.

6. The plasma generating apparatus of claim 1, further comprising:
a central dielectric tube disposed in the center of the top surface of the chamber; and
a central antenna disposed around the central dielectric tube.

7. The plasma generating apparatus of claim 1, wherein
a direction of a magnetic field inside the peripheral dielectric tubes and a direction of a magnetic field inside the central dielectric tube are opposite to each other.

8. The plasma generating apparatus of claim 1, wherein
the chamber comprises:
a lower chamber of a metal material;
an upper chamber of a non-metal material continuously connected to the lower chamber; and
a top plate of a metal material to cover a top surface of the upper chamber, and
the chamber further comprises a side coil to cover a side surface of the upper chamber, the side coil generating inductively coupled plasma inside the chamber.
